(19) United States
(12) Patent Application Publication
(10) Pub. No.: US 2006/0030130 A1
(43) Pub. Date: Feb. 9, 2006

(54) METHOD OF DICING A WAFER

(76) Inventors: Shih-Feng Shao, Taipei Hsien (TW); Chen-Hsiung Yang, Taipei Hsien (TW); Hsin-Ya Peng, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 10/711,997

(22) Filed: Oct. 19, 2004

(30) Foreign Application Priority Data
Aug. 9, 2004 (TW) 093123843

(51) Int. Cl. H01L 21/78; H01L 21/50

(52) U.S. Cl. 438/464; 438/113; 438/460

(57) ABSTRACT

A wafer supported by a carrier is provided where a bonding layer and an extendable film are disposed in between the carrier and the wafer. Then, a photoresist pattern is formed on a surface of the wafer to define scribe lines of the wafer. Following that, an anisotropic etching process is performed to remove the wafer uncovered by the photoresist pattern to form a plurality of dies. Finally the bonding layer is separated from the carrier.

### BACKGROUND OF INVENTION

1. Field of the Invention

The present invention relates to a method of dicing a wafer, and more particularly, to a method that allows automatic wafer expansion and wafer sorting after dicing the wafer.

2. Description of the Prior Art

In the fabrication of semiconductor chips or MEMS chips, a wafer is first treated with tens or more than hundreds of processes to form a plurality of semiconductor devices or MEMS devices. The wafer is subsequently diced by a dicing process to form a plurality of dies. The dies are thereafter packaged so as to form a plurality of chips able to be electrically connected to printed circuit boards.

Please refer to FIG. 1, which is a schematic diagram illustrating a conventional method of performing a dicing process with a dicing apparatus. As shown in FIG. 1, a wafer 10 to undergo a dicing process is bonded to a bonding layer 12, such as a tape. The bonding layer 12 meanwhile is bonded to a supporting frame 14 so as to fasten the position of the wafer 10. When the wafer 10 is accurately aligned in the dicing apparatus, a cutter 16 is exploited through predetermined scribe lines to segment the wafer 10 into a plurality of dies 18. Selectively, a wafer expansion process can be performed according to the dimension of the scribe lines by expanding the bonding layer 12, so as to enlarge the gap between two adjacent dies 18 for the convenience of a further wafer sorting process.

The above method is the most common way to dice the wafer 10. However, since the width of the cutter 16 is no longer ignorable as the critical dimension of semiconductor processes decreases, the dicing process using the cutter 16 is no longer able to dice a wafer with high integration. Therefore, a dicing process by way of etching is another choice.

Please refer to FIG. 2, which is a conventional method of performing a dicing process in an etching manner. As shown in FIG. 2, a wafer 30, having a photoresist pattern 36 disposed thereon for defining scribe lines, is bonded to a carrier 34 with a bonding layer 32. Then, an anisotropic etching process is performed to etch the wafer 30 uncovered by the photoresist pattern 36 until the wafer 30 is etched through so as to form a plurality of dies 38.

The above method is able to reduce the dimension of the scribe lines so as to increase the amounts of dies 30 arranged in the wafer. However, due to the narrowness of the scribe lines, the wafer sorting process cannot be easily performed after the dicing process. In addition, since the carrier 34, such as a bare wafer, is a rigid structure, the wafer expansion process in which the bonding layer 32 is extended to increase the gap of the dies 38 cannot be carried out. In such a case, the photoresist pattern 36 is removed in advance, and then the bonding layer 32 is removed to separate the dies 38 from the carrier 34. Following that, the dies 38 are picked up and sorted manually. Accordingly, the throughput is reduced and the dies 38 may be damaged.

### SUMMARY OF INVENTION

It is therefore a primary object of the claimed invention to provide a method of dicing a wafer to overcome the aforementioned problems.

According to the claimed invention, a method of dicing a wafer is disclosed. First, a wafer supported by a carrier is provided where a bonding layer and an extendable film are disposed in between the carrier and the wafer. Then, a photoresist pattern is formed on a surface of the wafer to define scribe lines of the wafer. Following that, an anisotropic etching process is performed to remove the wafer uncovered by the photoresist pattern to form a plurality of dies. Finally the bonding layer is separated from the carrier.

The present invention utilizes a bonding layer and an extendable film to bond the wafer and the carrier, and separates the bonding layer from the carrier without harming the extendable film (e.g. by heating or irradiating) after the dicing process. Consequently, an automatic wafer expansion process can be directly carried out to increase the gap between adjacent dies for the convenience of following die sorting and placing (welding) processes.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram illustrating a conventional method of performing a dicing process with a dicing apparatus.

FIG. 2 shows a conventional method of performing a dicing process by etching.

FIG. 3 through FIG. 8 are schematic diagrams illustrating a method of performing a dicing process according to a preferred embodiment of the present invention.

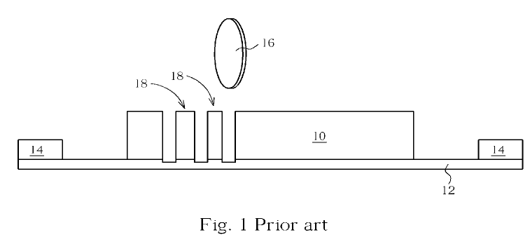

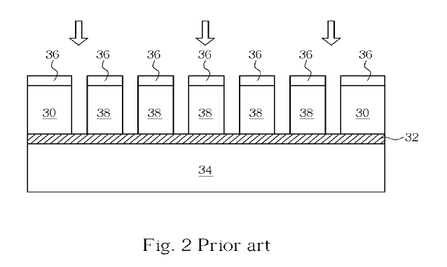

### DETAILED DESCRIPTION

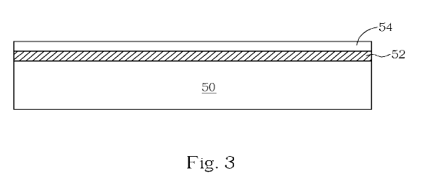

Please refer to FIG. 3 through FIG. 8. FIG. 3 through FIG. 8 are schematic diagrams illustrating a method of performing a dicing process according to a preferred embodiment of the present invention. As shown in FIG. 3, a carrier 50, e.g. a bare wafer, is provided, and a bonding layer 52 and an extendable film 54 are consecutively formed on the surface of the carrier 50. The extendable film 54 is an extendable and adhesive film, such as a plastic tape. The bonding layer 52 is a heat sensitive tape which can be removed by heating, a UV tape which can be removed by UV curing, or other material which can be easily removed without harming the adhesion of the extendable film 54.

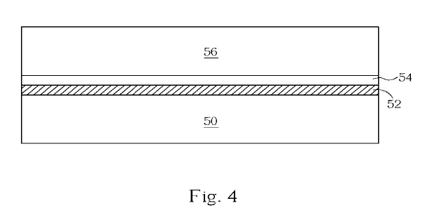

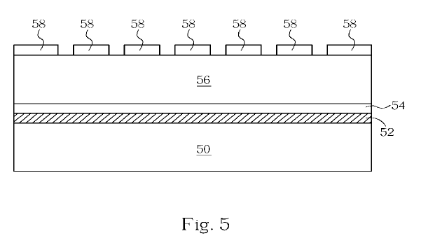

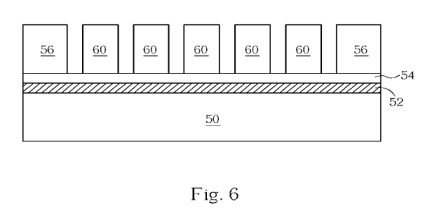

As shown in FIG. 4, a wafer 56 is then adhered and fastened to the surface of the extendable film 54. As shown in FIG. 5, a photoresist layer (not shown) is disposed on the wafer 56, and an exposure and development process is subsequently performed to form a photoresist pattern 58 so as to define the scribe lines on the surface of the wafer 56. As shown in FIG. 6, an anisotropic process, such as a dry etching process, is thereafter performed to etch the wafer 56 uncovered by the photoresist pattern 58 until the wafer 56 is etched through, so as to form a plurality of dies 60.

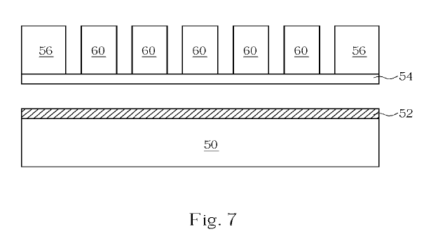

As shown in FIG. 7, the photoresist pattern (not shown) is stripped. Following that, the bonding layer 52 is removed so that the extendable film is separated from the carrier 50. The step of separating the extendable film 54 from the carrier 50 is based on the characteristic of the bonding layer 52. For example, if a heat sensitive tape is utilized as the bonding layer 52, the extendable film 54 and the carrier 50 are separated by heating. It is appreciated that the melting point of the extendable film 54 must be higher than the melting point of the bonding layer 52 so that the adhesion of the extendable film 54 is maintained. Otherwise, the dies 60 may be loosen from the extendable film 54. On the other hand, if a UV tape is utilized as the bonding layer 52, the extendable film 54 and the carrier 50 are separated in an irradiation manner, such as by UV curing.

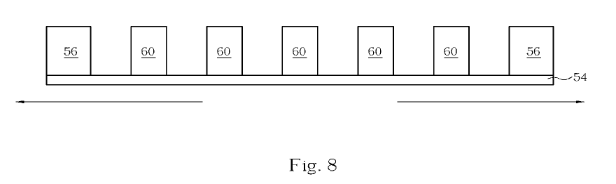

As shown in FIG. 8, after the extendable film 54 is separated from the carrier 50, the extendable film 54 can be easily extended due to its extendable characteristic. Consequently, an automatic wafer expansion process can be directly implemented to increase the gap between adjacent dies 60, and therefore a following automatic die sorting and die placing process can be carried out without any difficulties.

It can be seen that the method of dicing a wafer according to the present invention utilizes a bonding layer and an extendable film to bond the wafer and the carrier, and separates the bonding layer from the carrier without harming the extendable film (e.g. by heating or irradiating) after the dicing process. Consequently, an automatic wafer expansion process can be directly carried out to increase the gap between adjacent dies for the convenience of subsequent die sorting and placing processes.

In comparison with the prior art, the dicing process of the present invention is implemented by anisotropic etching, and thus the dimension of the scribe lines is more refined. In addition, the method of the present invention allows directly performing an automatic wafer expansion process and an automatic die sorting process. On the contrary according to the conventional method, the wafer expansion process must be carried out manually, thereby reducing the yield and prolonging production time.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of dicing a wafer, comprising:
providing a carrier, the carrier consecutively having a bonding layer and an extendable film positioned thereon;
providing a wafer, and bonding the wafer to the extendable film through a bottom surface of the wafer;
performing a dicing process to dice the wafer into a plurality of dies; and
separating the extendable film from the carrier.

2. The method of claim 1, wherein the bonding layer is a heat sensitive tape.

3. The method of claim 2, wherein separating the extendable film from the carrier is implemented by heating.

4. The method of claim 3, wherein the extendable film is an extendable tape, and the melting point of the extendable tape is higher than the melting point of the heat sensitive tape.

5. The method of claim 1, wherein the bonding layer is a UV tape.

6. The method of claim 5, wherein separating the extendable film from the carrier is implemented by UV curing.

7. The method of claim 6, wherein the extendable film is an extendable tape.

8. The method of claim 1, wherein the dicing process comprises:
forming a photoresist pattern on a top surface of the wafer to define scribe lines of the wafer; and
performing an anisotropic etching process to remove the wafer uncovered by the photoresist pattern.

9. The method of claim 8, further comprising removing the photoresist pattern after the dicing process is finished.

10. The method of claim 1, further comprising performing a wafer expansion and wafer sorting process after the extendable film is separated from the carrier.

11. A method of dicing a wafer, comprising:
providing a wafer, the wafer being supported by a carrier; and a bonding layer and an extendable film being positioned between the carrier and the wafer;
forming a photoresist pattern on a surface of the wafer to define scribe lines of the wafer;
performing an anisotropic etching process to remove the wafer uncovered by the photoresist pattern to form a plurality of dies; and
separating the bonding layer from the carrier.

12. The method of claim 11, wherein the bonding layer is a heat sensitive tape.

13. The method of claim 12, wherein separating the extendable film from the carrier is implemented by heating.

14. The method of claim 13, wherein the extendable film is an extendable tape, and the melting point of the extendable tape is higher than the melting point of the heat sensitive tape.

15. The method of claim 11, wherein the bonding layer is a UV tape.

16. The method of claim 15, wherein separating the extendable film from the carrier is implemented by UV curing.

17. The method of claim 16, wherein the extendable film is an extendable tape.

18. The method of claim 11, further comprising removing the photoresist pattern after the anisotropic etching process is finished.

19. The method of claim 11, further comprising performing a wafer expansion and wafer sorting process after the bonding layer is separated from the carrier.
